(19) United States
(12) Patent Application Publication
(10) Pub. No.: US 2021/0343527 A1
(43) Pub. Date: Nov. 4, 2021

(54) PATTERNING FOR SELECTIVE EJECTIONS OF PRINTABLE AMMONIUM-BASED CHALCOGENOMETALATE FLUIDS

(71) Applicant: Hewlett-Packard Development Company, L.P., Spring, TX (US)

(72) Inventors: Robert Ionescu, Palo Alto, CA (US); Helen A. Holder, Palo Alto, CA (US); Jarrid Wittkopf, Palo Alto, CA (US)

(73) Assignee: Hewlett-Packard Development Company, L.P., Spring, TX (US)

(21) Appl. No.: 17/286,574

(22) PCT Filed: Dec. 10, 2018
(86) PCT No.: PCT/US2018/064771

§ 371 Date: Apr. 19, 2021

(51) Int. Cl. H01L 21/02; C23C 18/12

(52) U.S. Cl. CPC H01L 21/02628; C23C 18/1204; H01L 21/02639; H01L 21/02568

(57) ABSTRACT

A method that includes selectively ejecting, from a first nozzle, a patterning material on to a surface of a substrate to define an area within to eject a first printable ammonium-based chalcogenometalate fluid; ejecting, from a second nozzle, the first printable ammonium-based chalcogenometalate fluid within the area defined by the patterning material to form a first layer of the printable ammonium-based chalcogenometalate fluid; and heating the first layer of printable ammonium-based chalcogenometalate fluid to dissipate the first printable ammonium-based chalcogenometalate fluid into a transition metal dichalcogenide having the form MX₂.

### BACKGROUND

A semiconductor refers to any material that has an electrical conductivity between a conductor and an insulator. Such semiconductors are used in various applications including field effect transistors (FETs), optoelectronics, photodetectors, phototransistors, photosensors, photovoltaic cells and light-emitting diodes (LEDs). A two-dimensional (2D) semiconductor is a semiconductor having a thickness on the atomic scale.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a flowchart showing a method according to an example of the principles described herein.

FIG. 2 is a block diagram of a printing device according to an example of the principles described herein.

FIG. 3 is a flowchart depicting a method of forming a semiconductor device according to an example of the principles described herein.

FIG. 4 is a process diagram of forming a semiconductive device according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

A semiconductor refers to any material that has an electrical conductivity between a conductor and an insulator. Such semiconductors are used in various applications including field effect transistors (FETs), optoelectronics, photodetectors, phototransistors, photosensors, photovoltaic cells and light-emitting diodes (LEDs). A two-dimensional (2D) semiconductor is a semiconductor with a thickness on the atomic scale. 2D semiconductors may be used in components for next generation electronics that have reduced form factors, for example.

One such material that is used in these 2D semiconductors is a transition metal dichalcogenide (TMD) which is a combination of a transition metal and a chalcogen and has the form MX₂. As described herein, such 2D semiconductors offer great potential in improving electronic device functionality. For example, poor energy efficiency in optoelectronics can be greatly improved using 2D semiconductive materials that have a direct bandgap in the visible light. Unlike the indirect bandgap of silicon, a 2D layered semiconductor has a direct bandgap single-layer. This direct bandgap is effective and relevant in light emission applications and for use with other light-based devices. In another example, transistors formed using 2D layered semiconductors provide high electron mobility, provide a high on/off ratio, and facilitate transparent ultra-thin devices.

While semiconductors, and 2D semiconductors in particular, have undoubtedly advanced electrical and electronic developments in general and will inevitably continue to do so, some characteristics impede their more complete implementation. For example, manufacturing these 2D semiconductors can rely on a chemical vapor deposition (CVD) system that uses powder precursors, specifically oxides such as molybdenum trioxide (MoO3) and tungsten trioxide (WO3). These oxides result in non-uniform growth of the semiconductive material. This non-uniform growth may reduce the certainty of semiconductor shape and size, thus reducing the semiconductor's practical implementation. Moreover, CVD processes are based on nucleation, which can include numerous heating cycles which are dirty and time consuming. For example, some heating cycles may take between 2-3 hours. In some cases, such as for the manufacturing of field effect transistors, the manufacturing is performed in a clean room. As a result of the use of the clean rooms, the complexity and cost in manufacturing these field effect transistors is increased. For example, CVD processes can implement a quartz tube which is to be cleaned and maintained after the CVD operation for proper operation and manufacturing. These complications are exacerbated if a heterogeneous structural stack of these semiconductors is formed, which can include multiple CVD operations.

In some examples described herein, the semiconductive material may be deposited onto a surface using an ejection device from, for example, a printhead or pen having a nozzle. In order to do this, the semiconductive material may be ejected in a fluid. A specific example of this fluid may be a printable ammonium-based chalcogenometalate fluid that may be heated to transition it into a metal dichalcogenide. However, a shape of the semiconductive material may not be defined due to the flow properties of the fluids used. These relatively poorly defined layers of deposited layers may vary based on the type of substrate. Regardless of the substrate, however, control of the deposition of the fluid resulting in shape edges prevents the different ejected materials from mixing, provides for accurate traces for either vertical or horizontal edge electrical contact points, and further provides for customized layer thicknesses.

The present specification describes a method that includes selectively ejecting, from a first nozzle, a patterning material on to a surface of a substrate to define an area within to eject a first printable ammonium-based chalcogenometalate fluid; ejecting, from a second nozzle, the first printable ammonium-based chalcogenometalate fluid within the area defined by the patterning material to form a first layer of the printable ammonium-based chalcogenometalate fluid; and heating the first layer of printable ammonium-based chalcogenometalate fluid to dissipate the first printable ammonium-based chalcogenometalate fluid into a transition metal dichalcogenide having the form MX₂.

The present specification further describes a printing device, that includes a pen to eject: a patterning material on a substrate to define an area within to eject a first printable ammonium-based chalcogenometalate fluid; and an amount of a printable ammonium-based chalcogenometalate fluid, the pen including: a firing chamber to hold the amount of printable ammonium-based chalcogenometalate fluid; an orifice; an ejector to eject the amount of printable ammonium-based chalcogenometalate fluid through the orifice; and a reservoir to supply the printable ammonium-based chalcogenometalate fluid to the pen; and a patterning material curing device to selectively cure the patterning material.

The present specification also describes a method of forming a semiconductor device that includes selectively depositing a patterning material on a substrate to form an area into which a printable ammonium-based chalcogenometalate fluid may be restrained; curing the patterning material; depositing the printable ammonium-based chalcogenometalate fluid; heating the layer of first printable ammonium-based chalcogenometalate fluid to dissipate the first printable ammonium-based chalcogenometalate fluid into a transition metal dichalcogenide having the form MX₂ with the first dopant distributed therethrough; and removing the patterning material from the substrate.

As used in the present specification and in the appended claims, the term “chalcogenometalate” may refer to transition metal thiometalates, or transitional metal-chalcogen compounds.

As used in the present specification and in the appended claims, the term “ammonium-based” may refer to a compound that includes the molecule NH₄.

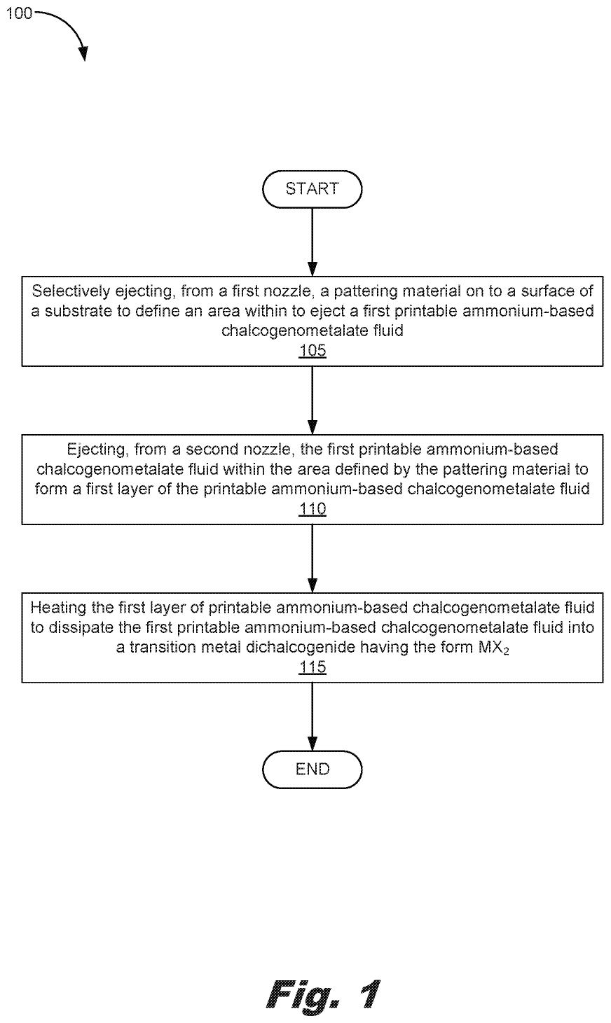

Turning now to the figures, FIG. 1 is a flowchart showing a method (100) according to an example of the principles described herein. The method (100) may include selectively ejecting (105), from a first nozzle, a patterning material on to a surface of a substrate to define an area within to eject a first printable ammonium-based chalcogenometalate fluid. As described herein, the nozzle may form part of a printhead or other device that is used to transport the patterning material, and any fluid described herein, from a reservoir and out of the nozzle. In order to accomplish the methods and functionalities described herein, the printhead may include, in some examples, a firing chamber to hold an amount of fluid therein and a fluid ejection device to eject an amount of fluid out of the firing chamber and through the nozzle. The ejection device may be any device that may force an amount of fluid within the firing chamber such as a piezoelectric device or a thermosensitive device. In any example, a processor may send signals to the ejection device in order to selectively cause the ejection of any fluid out of the nozzle and onto a portion of a substrate.

The patterning material may be any material that prevents the flow of any fluid subsequently deposited on the substrate. In an example, the patterning material may include a Poly(methyl methacrylate) (PMMA), polydimethylsiloxane (PDMS), a photoresist (i.e., a photopolymeric photoresist, a photodecomposing photoresist, or a photocrosslinking photoresist), a resist (i.e., a wax, a grease, and a stencil, among others), a polymer, and a resin, among others. In any example presented herein, the patterning material may be placed in locations on the substrate where subsequent fluids are not to be placed. In certain examples, the patterning material may be used to encircle an amount of fluid to be deposited within the barrier created by the patterning material to as to contain the fluid and prevent the fluid from flowing out of the barrier during deposition.

In some examples, the printable ammonium-based chalcogenometalate fluid may be used as a printing fluid such as an ink. As with printing fluid, the printable ammonium-based chalcogenometalate fluid is deposited on a substrate along with the patterning material. The printable ammonium-based chalcogenometalate fluid may be deposited on the substrate in any particular pattern in order to form, for example, the semiconductors as described herein. That is, the printable ammonium-based chalcogenometalate fluid may be printable so as to form any shape, such as a logo, to form a semiconductor on a substrate in the same shape, i.e., the logo among other shapes. After deposition, the printable ammonium-based chalcogenometalate fluid is treated such that a transition metal dichalcogenide (TMD) is left. The transition metal dichalcogenide is a 2D semiconductive material that is one atomic layer thick. As described herein in more detail, the ammonium-based chalcogenometalate fluid may be printable and may be printed into any shape and printed on any substrate as defined by the patterning material previously deposited on the substrate.

In an example, the printable ammonium-based chalcogenometalate fluid may include an ammonium-based chalcogenometalate precursor that may serve as the base of the fluid. The ammonium-based chalcogenometalate precursor may, in an example, have the form (NH₄)₂MX₄. In this example, “M”, is a transition metal element as classified on a periodic table. Specific examples of transition metals of the present specification may include molybdenum and tungsten; however, other transition metals may be implemented as well. The “X” is a chalcogen element as classified on the periodic table. Examples of chalcogen elements include oxygen, sulfur, selenium, and tellurium. Specific examples of ammonium-based chalcogenometalate precursors having the form (NH₄)₂MX₄ that may be found in the printable ammonium-based transition metal fluid include ammonium tetrathiotungstate, (NH₄)₂WS₄, and ammonium tetrathiomolybdate, (NH₄)₂MoS₄.

While specific reference is made to particular ammonium-based chalcogenometalate precursors, a variety of ammonium-based chalcogenometalate precursors may be used. These ammonium-based chalcogenometalate precursors may be developed to form part of the printable ammonium-based chalcogenometalate fluid or an ammonium-based chalcogenometalate printing fluid. These fluids may be printed directly on substrates such as a metallic substrate. In another example, the substrate may be a graphene substrate which has properties used in connection with electrical or electronic applications. In any example presented herein, the substrate is selected from the group consisting of: graphene, glass, polyethylene terephthalate, aluminum, quartz, sapphire, silicon, silicon dioxide, copper, nickel, ceramics, and gold.

The printable ammonium-based chalcogenometalate fluid may, in an example, include an aqueous solvent. The aqueous solvent dissolves the ammonium-based chalcogenometalate precursor which may be formed into a powder form prior to mixing with the aqueous solvent. The aqueous solvent may be any type of solvent including dimethyl sulfoxide (DMSO); dimethylformamide (DMF); N-methyl-20prrolidone (NMP); and 1,2-Hexanediol, among other -diol based solvents. While specific reference is made to particular aqueous solvents, a variety of aqueous solvents may be used, which solvents may be selected based on the ammonium-based chalcogenometalate precursor that is used.

The printable ammonium-based chalcogenometalate fluid may include water. The aqueous solvent and water may be mixed in any variety of ratios to achieve a printable concentration of the printable ammonium-based chalcogenometalate fluid. For example, the aqueous solvent and water may be found in a ratio of 2 to 3: two parts aqueous solvent to three parts water. However, any mixture ratio may be used to achieve different properties. In an example, these different properties may include different viscosities.

In some examples, the various components of the printable ammonium-based chalcogenometalate fluid, i.e., the ammonium-based chalcogenometalate precursor, the aqueous solvent, and the water, as well as the amounts and ratios of each component, may be selected based on the substrate onto which the printable ammonium-based chalcogenometalate fluid is to be printed. The printable ammonium-based chalcogenometalate fluid may be printed on numerous substrates. Examples of substrates that can be printed on include graphene, glass, polyethylene terephthalate, aluminum, quartz, sapphire, silicon, silicon dioxide, copper, nickel, ceramics, and gold. As described herein, the specific composition and mixture of the printable ammonium-based chalcogenometalate fluid may be dependent upon the particular substrate selected.

The printable ammonium-based chalcogenometalate fluid may, in an example, also include a dopant. The dopant may be any trace impurity element represented on the periodic table of elements that is added into the printable ammonium-based chalcogenometalate fluid in order to alter the electrical or optical properties of the substance. In specific examples, the dopant may be any one of F4TCNQ (C₁₂F₄N₄); tetracyanoquinodimethane (TCNQ); 1-Ethyl-3-methylimidazolium bis(trifluoromethylsulfonyl)imide ([EMIM]-[TFSI]), C₂₀H₂₈N₄O₄ (PDPP3T); C₄H₄S (thiophene); and dihydronicotinamide adenine dinucleotide (NADH). In a specific example, F4TCNQ (C₁₂F₄N₄) may be used as a p-type dopant. In an example, NADA may be used as an n-type dopant. Other dopants include, but are not limited to, boron (B), arsenic (As), phosphorus (P), antimony (Sb), aluminum (Al), gallium (GA), sulfur (S), selenium (Se), tellurium (Te), silicon (Si), germanium (Ge), magnesium (Mg), zinc (Zn), cadmium (Cd), erbium (Er), europium (Eu), neodymium (Nd), holmium (Ho), and neodymium yttrium aluminum garnets (YAGs), among others.

In an example, the dopant can enhance photocurrent and photoluminescence of the semiconductor materials giving the semiconductors a relatively better or new property. The method in which these example fluids are applied to create any semiconductor structures overcomes any inferiorities of, for example, a chemical vapor deposition (CVD) process. Indeed, the described methods presented herein achieve the ability to pattern semiconductive materials that include a printable ammonium-based chalcogenometalate fluid. By adjusting the placement of the patterning material, specifically structured semiconductive devices may be formed. In some examples, the electron transport, photocurrent, and photoluminescence of the semiconductor may be enhanced through the use of a dopant as described.

The method (100) may include ejecting (110), from a second nozzle, the first printable ammonium-based chalcogenometalate fluid within the area defined by the patterning material to form a first layer of the printable ammonium-based chalcogenometalate fluid. As described herein, the patterning material may define the metes and bounds of the area in which the printable ammonium-based chalcogenometalate fluid may flow after ejection (110) from the nozzle. In this example, the patterning material may act as a fluidic dam that prevents the uncontrolled flow of the printable ammonium-based chalcogenometalate fluid.

The method (100) may also include heating (115) the first layer of printable ammonium-based chalcogenometalate fluid to dissipate the first printable ammonium-based chalcogenometalate fluid into a transition metal dichalcogenide having the form MX₂. In this example, along with the printhead described herein, the printing device operating the printhead may also include a heating device that increases the temperature of the printable ammonium-based chalcogenometalate fluid. In an example, the heating (115) the layer of the first printable ammonium-based chalcogenometalate fluid comprises heating the layer of the first printable ammonium-based chalcogenometalate fluid to a temperature of 280-500 degrees Celsius.

In an example, the patterning material may also be hardened or cured using the heating device. Thus, in an example, the method (100) may also include heating the patterning material prior to ejection of the first printable ammonium-based chalcogenometalate fluid out of the second nozzle. Indeed, in any example, the ejection (105) of the patterning material, the heating of the patterning material, the ejection (110) of the first printable ammonium-based chalcogenometalate fluid, and the heating (115) of the first printable ammonium-based chalcogenometalate fluid may be conducted any number of times in order to build up, layer-by-layer, materials that have been deposited over other materials. This, accordingly, may result in the formation of a three-dimensional layered semiconductor.

In any example presented herein, the method (100) may also include ejecting, from a third nozzle, a second printable ammonium-based chalcogenometalate fluid over the first layer of the printable ammonium-based chalcogenometalate fluid to form a second layer of printable ammonium-based chalcogenometalate fluid. This second printable ammonium-based chalcogenometalate fluid may include an ammonium-based chalcogenometalate precursor different from the first layer of the printable ammonium-based chalcogenometalate fluid. As described herein, this second printable ammonium-based chalcogenometalate fluid may also be heated by the heating device.

The method (100) may also include, at any time during the formation of a semiconductive device, the removal of the patterning material. The patterning material may be removed using a number of different processes including ultrasonic cleaning, chemical dissolving, scrapping, or any other similar process. The process used to remove the patterning material may be dependent on the type of patterning material used. In any example, however, the printing device implementing the method (100) described herein, may include any device to accomplish the removal of the patterning material such as an ultrasonic device, a wash bath, or other instruments.

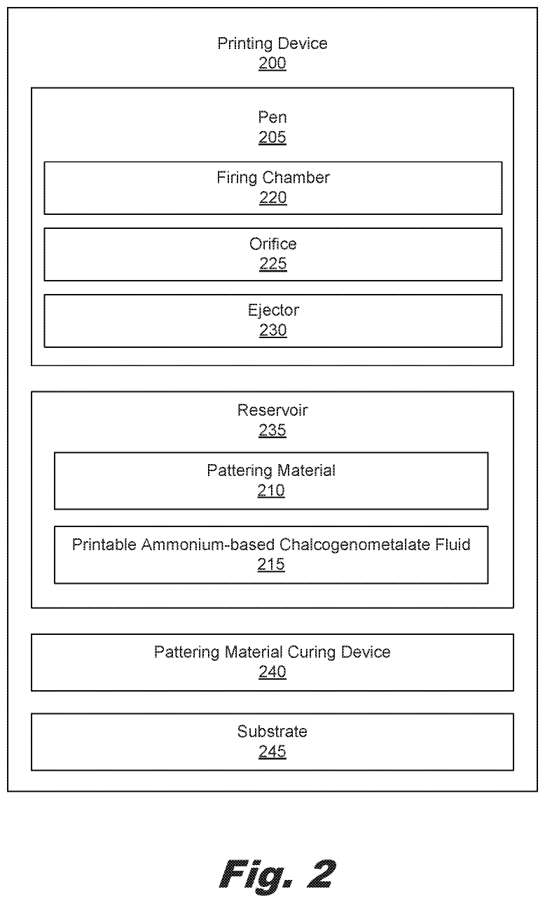

FIG. 2 is a block diagram of a printing device (200) according to an example of the principles described herein. As described herein, the printing device (200) may include a pen (205) to eject a patterning material (210) on a substrate (245) to define an area within to eject a first printable ammonium-based chalcogenometalate fluid and an amount of a printable ammonium-based chalcogenometalate fluid (215). The pen (205) described herein, may include any devices similar to the printhead described herein and, in some examples, may include more or fewer elements described in connection with the printhead. In an example, the pen (205) may comprise a plurality of printheads that each operate independently of each other in order to deposit the patterning material (210) and/or printable ammonium-based chalcogenometalate fluid (215) onto the substrate (245).

Similar to the printhead described herein in connection with FIG. 1, the pen (205) may include a firing chamber (220), an ejector (230), and an orifice (225). The firing chamber (220) may accumulate an amount of either patterning material (210) or printable ammonium-based chalcogenometalate fluid (215) therein. The firing chamber (220) may include an ejector (230) to eject an amount of the accumulated patterning material (210) or printable ammonium-based chalcogenometalate fluid (215) out of the orifice (225) in order to selectively eject these substances onto the substrate (245). The term “selectively eject” as used in the present specification and in the appended claims refers to the ejection of any substance on the substrate (245) at any time and at any location on the substrate (245). Thus, the pen (205) described herein, may form any layout on the substrate (245) of either of the patterning material (210) or printable ammonium-based chalcogenometalate fluid (215) on the substrate (245).

The patterning material (210) and printable ammonium-based chalcogenometalate fluid (215) may be maintained in any number of reservoirs (235). The reservoirs (235) are fluidically coupled to the or a plurality of firing chambers (220) in order to provide for the selective ejection of the patterning material (210) and/or printable ammonium-based chalcogenometalate fluid (215). In an example, the individual reservoirs (235) may maintain the patterning material (210) and two types of printable ammonium-based chalcogenometalate fluids (215) so as to provide a corresponding individual pen (205) with the corresponding ejectable material.

The printing device (200) may also include a patterning material curing device (240). The patterning material curing device (240) may be any device that cures or otherwise renders resilient and immiscible the patterning material (210) relative to any printable ammonium-based chalcogenometalate fluid (215). Examples include heat lamps and ultraviolet lamps, among others. In an example, the patterning material curing device (240) is a heat lamp that is used in-line with the pen (205) during the method (100) described herein.

The printing device (200) may further include a substrate (245). The substrate (245) may be, in an example, a removable substrate that is received by the printing device (200) and augmented via the ejection, by the ejector (230), of the patterning material (210) and/or printable ammonium-based chalcogenometalate fluids (215) described herein. The substrate (245), in an example, may be a build platform within the printing device (200).

As described herein, during operation of the printing device (200), a processor of the printing device (200) may direct the ejector (230) to selectively eject an amount of the patterning material (210) and printable ammonium-based chalcogenometalate fluids (215) onto the substrate (245). This is done by continuously directing a pump to pump an amount of patterning material (210) and printable ammonium-based chalcogenometalate fluid (215) into fluidically coupled firing chambers (220) within the pens (205). The process may further include selectively ejecting, with the individual ejectors (230), amounts of patterning material (210) and printable ammonium-based chalcogenometalate fluids (215). The printing device (200) may further include any translation motors to translate the pen (205) or substrate (245) relative to each other so as to deposit the patterning material (210) and printable ammonium-based chalcogenometalate fluid (215) at predetermined locations on the substrate (245). During curing processes as described herein, the patterning material curing device (240) may be moved over locations on the substrate (245) where the patterning material (210) has been deposited. The processor directing these actions may execute any computer readable program code in order to cause signals to be sent to these devices in order to accomplish the functionalities of these devices.

In order to achieve some additional functionality, the printing device (200) may include various hardware components. Among these hardware components may be the processor described herein, a number of data storage devices, a number of peripheral device adapters, and a number of network adapters. These hardware components may be interconnected through the use of a number of busses and/or network connections. In one example, the processor, data storage device, peripheral device adapters, and network adapter may be communicatively coupled via a bus.

The processor may include the hardware architecture to retrieve executable code from the data storage device and execute the executable code. The executable code may, when executed by the processor, cause the processor to implement at least the functionality of selectively ejecting, from a first nozzle, a patterning material on to a surface of a substrate to define an area within to eject a first printable ammonium-based chalcogenometalate fluid; ejecting, from a second nozzle, the first printable ammonium-based chalcogenometalate fluid within the area defined by the patterning material to form a first layer of the printable ammonium-based chalcogenometalate fluid; and heating the first layer of printable ammonium-based chalcogenometalate fluid to dissipate the first printable ammonium-based chalcogenometalate fluid into a transition metal dichalcogenide having the form MX₂, according to the methods of the present specification described herein. In the course of executing code, the processor may receive input from and provide output to a number of the remaining hardware units.

The data storage device may store data such as executable program code that is executed by the processor or other processing device. The data storage device may specifically store computer code representing a number of applications that the processor executes to implement at least the functionality described herein.

The data storage device may include various types of memory modules, including volatile and nonvolatile memory. For example, the data storage device of the present example includes Random Access Memory (RAM), Read Only Memory (ROM), and Hard Disk Drive (HDD) memory. Many other types of memory may also be utilized, and the present specification contemplates the use of many varying type(s) of memory in the data storage device as may suit a particular application of the principles described herein. In certain examples, different types of memory in the data storage device may be used for different data storage needs. For example, in certain examples the processor may boot from Read Only Memory (ROM), maintain nonvolatile storage in the Hard Disk Drive (HDD) memory, and execute program code stored in Random Access Memory (RAM). In an example, the data storage device may include a computer readable medium, a computer readable storage medium, or a non-transitory computer readable medium, among others. For example, the data storage device may be, but not limited to, an electronic, magnetic, optical, electromagnetic, infrared, or semiconductor system, apparatus, or device, or any suitable combination of the foregoing. More specific examples of the computer readable storage medium may include, for example, the following: an electrical connection having a number of wires, a portable computer diskette, a hard disk, a random-access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store computer usable program code for use by or in connection with an instruction execution system, apparatus, or device. In another example, a computer readable storage medium may be any non-transitory medium that can contain, or store a program for use by or in connection with an instruction execution system, apparatus, or device.

The hardware adapters in the printing device (200) enable the processor to interface with various other hardware elements, external and internal to the printing device (200). For example, the peripheral device adapters may provide an interface to input/output devices, such as, for example, a display device, a mouse, or a keyboard. The peripheral device adapters may also provide access to other external devices such as an external storage device, a number of network devices such as, for example, servers, switches, and routers, client devices, other types of computing devices, and combinations thereof.

The display device may be included to allow a user of the printing device (200) to interact with and implement the functionality of the printing device (200). The peripheral device adapters may also create an interface between the processor and the display device, a printer, or other media output devices. The network adapter may provide an interface to other computing devices within, for example, a network, thereby enabling the transmission of data between the printing device (200) and other devices located within the network such as personal computing devices, servers, laptops, personal digital assistants (PDAs), and table devices, among others.

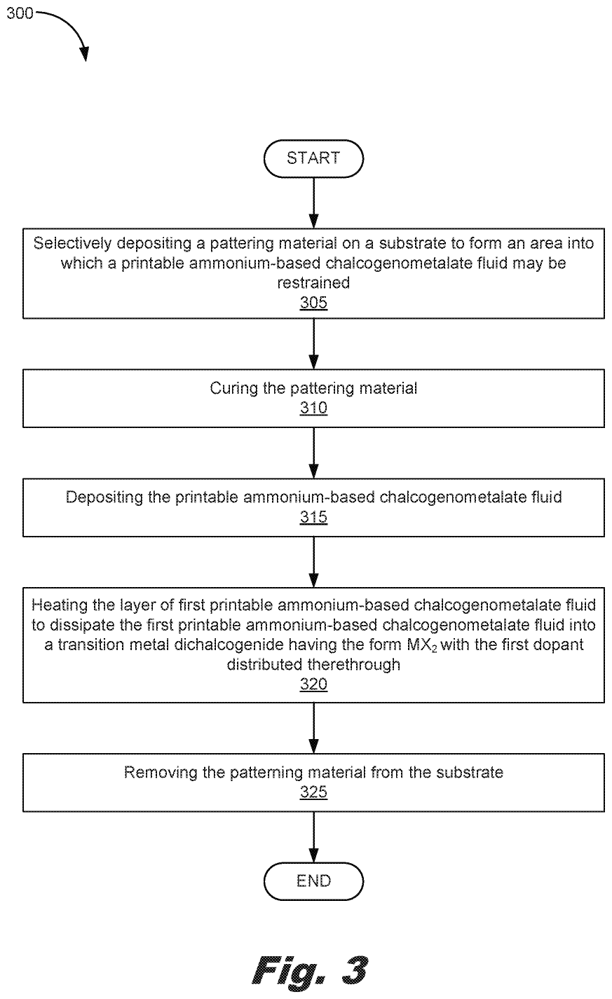

FIG. 3 is a flowchart depicting a method (300) of forming a semiconductor device according to an example of the principles described herein. The method (300) may include selectively depositing (305) a patterning material on a substrate to form an area into which a printable ammonium-based chalcogenometalate fluid may be restrained. The method (300) may further include curing (310) the patterning material so that the printable ammonium-based chalcogenometalate fluid (215) may be restrained as described.

The method (300) further includes depositing (315) the printable ammonium-based chalcogenometalate fluid. As described herein, the patterning material (210) and printable ammonium-based chalcogenometalate fluids (215) may be deposited onto a substrate (245) using any number of pens (205) designed to eject the patterning material (210) and printable ammonium-based chalcogenometalate fluid (215).

The method (300) may include heating the layer of first printable ammonium-based chalcogenometalate fluid (215) to dissipate the first printable ammonium-based chalcogenometalate fluid (215) into a transition metal dichalcogenide having the form MX₂ with the first dopant distributed therethrough. After the heating (320) of the printable ammonium-based chalcogenometalate fluid (215), the method (300) may include removing (325) the patterning material (210) from the substrate (245).

The method (300) may include any further depositions of either of the patterning material (210) and any layers of printable ammonium-based chalcogenometalate fluids (215) and further heating processes of these layers in order to either cure or harden the patterning material (210) and/or printable ammonium-based chalcogenometalate fluids (215) respectively.

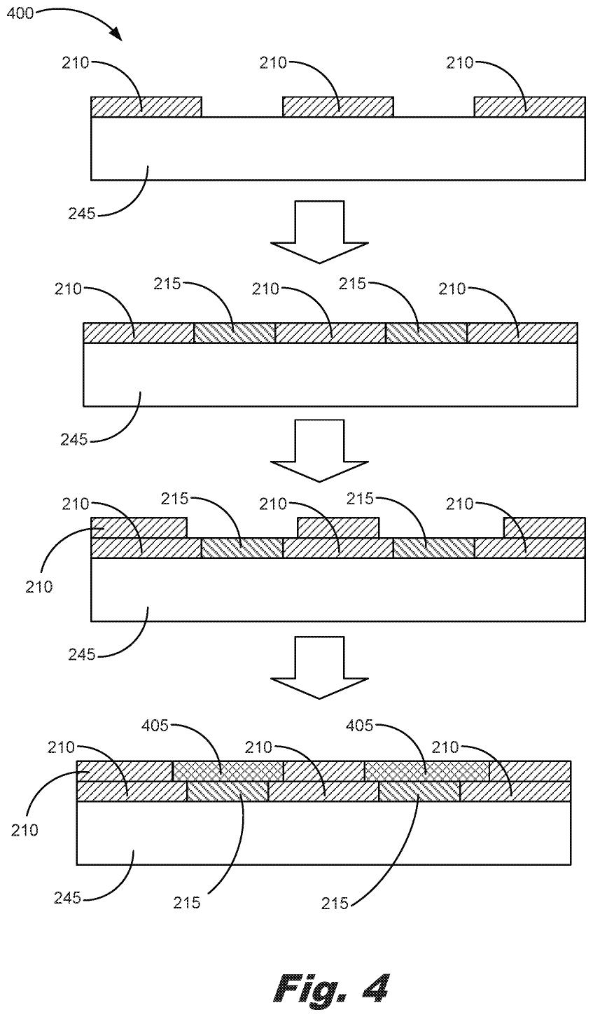

FIG. 4 is a process diagram (400) of forming a semiconductive device according to an example of the principles described herein. The process diagram first shows an amount of patterning material (210) deposited on a substrate (245). As described herein, the patterning material (210) may be cured to secure its position on the substrate (245). A printable ammonium-based chalcogenometalate fluid (215) may be deposited among the patterning material (210) such that the printable ammonium-based chalcogenometalate fluid (215) is prevented from flowing across the substrate (245) due to the placement patterning material (210).

The process (400) may include the application of a second layer of patterning material (210) in preparation to receive another or second layer of printable ammonium-based chalcogenometalate fluid (405). The second layer of printable ammonium-based chalcogenometalate fluid (405) may be different form the printable ammonium-based chalcogenometalate fluid (215) deposited earlier and, due to the placement of the second layer of patterning material (210), may exceed the dimensions of the printable ammonium-based chalcogenometalate fluid (215) previously deposited. The process (400) may conclude with washing away the first and second layers of patterning material (210) thereby exposing the semiconductive devices. At any time, any of the first layer of patterning material (210), second layer of patterning material (210), printable ammonium-based chalcogenometalate fluid (215), and second layer of printable ammonium-based chalcogenometalate fluid (405) may be cured using a curing device such as a heat lamp and/or UV light device.

Aspects of the present system and method are described herein with reference to flowchart illustrations and/or block diagrams of methods, apparatus (systems) and computer program products according to examples of the principles described herein. Each block of the flowchart illustrations and block diagrams, and combinations of blocks in the flowchart illustrations and block diagrams, may be implemented by computer usable program code. The computer usable program code may be provided to a processor of a general-purpose computer, special purpose computer, or other programmable data processing apparatus to produce a machine, such that the computer usable program code, when executed via, for example, the processor of the printing device (200) or other programmable data processing apparatus, implement the functions or acts specified in the flowchart and/or block diagram block or blocks. In one example, the computer usable program code may be embodied within a computer readable storage medium; the computer readable storage medium being part of the computer program product. In one example, the computer readable storage medium is a non-transitory computer readable medium.

The specification and figures describe a method and system for depositing a patterning material onto a substrate within a printing device prior to the application of a or a plurality of printable ammonium-based chalcogenometalate fluids. By laying out the patterning material prior to application of the printable ammonium-based chalcogenometalate fluids, the edges of any formed semiconductor devices may be cleaner and more well defined. This leads to better semiconductive properties to the formed semiconductive device. Additionally, various stacked shapes may be formed. Still further, heterostructures may also be formed that includes a plurality of layers of printable ammonium-based chalcogenometalate fluids using successively applied layers of patterning material. The time used to form the semiconductive may be reduced relative to, for example, a CVD process. Still further, with the application of the patterning material prior to the application of the printable ammonium-based chalcogenometalate fluid, any type of substrate may be used regardless of the flowability characteristics of the printable ammonium-based chalcogenometalate fluid relative to the substrate.

The preceding description has been presented to illustrate and describe examples of the principles described. This description is not intended to be exhaustive or to limit these principles to any precise form disclosed. Many modifications and variations are possible in light of the above teaching.

What is claimed is:

1. A method comprising:
selectively ejecting, from a first nozzle, a patterning material on to a surface of a substrate to define an area within to eject a first printable ammonium-based chalcogenometalate fluid;
ejecting, from a second nozzle, the first printable ammonium-based chalcogenometalate fluid within the area defined by the patterning material to form a first layer of the printable ammonium-based chalcogenometalate fluid; and
heating the first layer of printable ammonium-based chalcogenometalate fluid to dissipate the first printable ammonium-based chalcogenometalate fluid into a transition metal dichalcogenide having the form MX₂.

2. The method of claim 1, comprising ejecting, from a third nozzle, a second printable ammonium-based chalcogenometalate fluid over the first layer of the printable ammonium-based chalcogenometalate fluid to form a second layer of printable ammonium-based chalcogenometalate fluid.

3. The method of claim 2, comprising heating the second layer of printable ammonium-based chalcogenometalate fluid to dissipate the second printable ammonium-based chalcogenometalate fluid into a transition metal dichalcogenide having the form MX₂.

4. The method of claim 1, comprising curing the patterning material prior to ejecting, from the second nozzle, the first printable ammonium-based chalcogenometalate fluid within the area defined by the patterning material.

5. The method of claim 4, wherein the curing comprises applying a heat to the patterning material, applying an ultraviolet light to the patterning material, or combinations thereof.

6. The method of claim 1, comprising removing the patterning material after heating the first layer of printable ammonium-based chalcogenometalate fluid.

7. The method of claim 1, wherein heating the layer of the first printable ammonium-based chalcogenometalate fluid comprises heating the layer of the first printable ammonium-based chalcogenometalate fluid to a temperature of 280-500 degrees Celsius.

8. The method of claim 1, wherein the substrate is selected from the group consisting of: graphene, glass, polyethylene terephthalate, aluminum, quartz, sapphire, silicon, silicon dioxide, copper, nickel, ceramics, and gold.

9. The method of claim 1, wherein the first printable ammonium-based chalcogenometalate fluid comprises an ammonium-based chalcogenometalate precursor and wherein the ammonium-based chalcogenometalate precursor is formed by combining a fluid having the form (NH₄)₂MO_{y} with a gas having the form H₂X where:
M is the transition metal;
Y is a numeric value;
X is a chalcogen selected from the group consisting of:
sulfur;
selenium; and
tellurium.

10. A printing device, comprising:
a pen to eject:
a patterning material on a substrate to define an area within to eject a first printable ammonium-based chalcogenometalate fluid; and
an amount of a printable ammonium-based chalcogenometalate fluid, the pen comprising:
a firing chamber to hold the amount of printable ammonium-based chalcogenometalate fluid;
an orifice; and
an ejector to eject the amount of printable ammonium-based chalcogenometalate fluid through the orifice;
a reservoir to supply the printable ammonium-based chalcogenometalate fluid and patterning material to the pen; and
a patterning material curing device to selectively cure the patterning material.

11. The printing device of claim 10, wherein the first and second ammonium-based chalcogenometalate precursors have the form (NH₄)₂MX₄ wherein:
M is a transition metal; and
X is a chalcogen.

12. The printing device of claim 10, comprising a heat source to heat the printable ammonium-based chalcogenometalate fluid ejected.

13. A method of forming a semiconductor device, comprising:
selectively depositing a patterning material on a substrate to form an area into which a printable ammonium-based chalcogenometalate fluid may be restrained;
curing the patterning material;
depositing the printable ammonium-based chalcogenometalate fluid;
heating the layer of first printable ammonium-based chalcogenometalate fluid to dissipate the first printable ammonium-based chalcogenometalate fluid into a transition metal dichalcogenide having the form MX₂ with the first dopant distributed therethrough; and
removing the patterning material from the substrate.

14. The method of claim 13, wherein the curing comprises applying a heat to the patterning material, applying an ultraviolet light to the patterning material, or combinations thereof.

15. The method of claim 13, wherein the substrate is selected from the group consisting of: graphene, glass, polyethylene terephthalate, aluminum, quartz, sapphire, silicon, silicon dioxide, copper, nickel, ceramics, and gold.
